(19) United States
(12) Patent Application Publication
(10) Pub. No.: US 2026/0231528 A1
(43) Pub. Date: Aug. 6, 2026

(54) ARRAY SUBSTRATE AND DISPLAY PANEL

(71) Applicants: Beijing BOE Technology Development Co., Ltd., Beijing (CN); BOE TECHNOLOGY GROUP CO., LTD., Beijing (CN)

(72) Inventors: Lizhong WANG, Beijing (CN); Guangcai YUAN, Beijing (CN); Ce NING, Beijing (CN); Hui GUO, Beijing (CN)

(73) Assignees: Beijing BOE Technology Development Co., Ltd., Beijing (CN); BOE TECHNOLOGY GROUP CO., LTD., Beijing (CN)

(21) Appl. No.: 19/150,914

(22) PCT Filed: Jul. 31, 2024
(86) PCT No.: PCT/CN2024/109069

§ 371 Date: Jul. 25, 2025

(30) Foreign Application Priority Data
Jul. 31, 2023 (CN) 202310954089.4
Jul. 31, 2024 (CN) 202411047961.8

(51) Int. Cl. H10D 86/40; G02F 1/1335; G02F 1/1368

(52) U.S. Cl. CPC H10D 86/421; G02F 1/1368; H10D 86/441; G02F 1/133514

(57) ABSTRACT

An array substrate has a display region and a peripheral region and includes a base substrate, a first signal line, a first transistor and a second transistor. The first signal line is disposed on the base substrate and at least partially located in the display region. The first transistor is located in the display region and disposed on a side of the first signal line away from the base substrate. The first transistor includes a first semiconductor pattern and a first gate disposed on a side of the first semiconductor pattern away from the base substrate. The second transistor is located in the peripheral region. The second transistor includes a second semiconductor pattern and a second gate disposed on a side of the second semiconductor pattern away from the base substrate; and the first gate and the second gate are arranged in a same layer.

### CROSS-REFERENCE TO RELATED APPLICATIONS

This application is a national phase entry under 35 USC 371 of International Patent Application No. PCT/CN2024/109069, filed on Jul. 31, 2024, which claims priorities to Chinese Patent Application No. 202310954089.4, filed on Jul. 31, 2023 and Chinese Patent Application No. 202411047961.8, filed on Jul. 31, 2024, each are incorporated herein by reference in their entirety.

### TECHNICAL FIELD

The present disclosure relates to the field of display technologies, and in particular, to an array substrate and a display panel.

### BACKGROUND

In current liquid crystal display panels, the method for arranging the common electrode in the liquid crystal display panel varies. One method is to arrange both the common electrode and the pixel electrode in the array substrate, e.g., Advanced-Super Dimensional Switching (ADS) technology. ADS technology forms a multi-dimensional electric field by using, in a same plane, electric fields generated at edges of a slit-electrode and electric fields generated between a slit-electrode layer and a plate-like electrode layer, to cause liquid crystal molecules along all orientations, between the slit electrodes as well as over the electrodes, within a liquid crystal cell to rotate.

### SUMMARY

In an aspect, an array substrate is provided. The array substrate includes a base substrate, a first signal line, a first transistor and a second transistor. The first signal line is disposed on the base substrate, and is at least partially located in a display region. The first transistor is located in the display region and is disposed on a side of the first signal line away from the base substrate. The first transistor includes a first semiconductor pattern and a first gate disposed on a side of the first semiconductor pattern away from the base substrate. The second transistor is located in a peripheral region. The second transistor includes a second semiconductor pattern and a second gate disposed on a side of the second semiconductor pattern away from the base substrate. The first gate and the second gate are arranged in a same layer.

In some embodiments, the first semiconductor pattern includes a first channel region, and a first region and a second region that are respectively located on two sides of the first channel region. The array substrate further includes a first insulating layer, a second insulating layer, a first via hole and a first connection electrode. The first insulating layer is located between the first signal line and the first semiconductor pattern. The second insulating layer is located on the side of the first semiconductor pattern away from the base substrate. The first via hole penetrates through at least the first insulating layer and the second insulating layer, exposes at least part of the first signal line, and exposes at least part of the first region. The first connection electrode is disposed on a side of the second insulating layer away from the base substrate, and the first connection electrode is electrically connected to the first signal line and the first region in the first via hole.

In some embodiments, the first connection electrode and the first gate include a same material and are arranged in a same layer; and at least part of edges of the first connection electrode is in contact with the first region.

In some embodiments, the first region includes a first sub-portion and a second sub-portion located in the first via hole; the first sub-portion is in contact with the first connection electrode; the second sub-portion is adjacently connected to an edge of the first connection electrode; orthogonal projections of the second sub-portion and the first connection electrode on the base substrate do not overlap; and a conductivity of the second sub-portion is greater than a conductivity of the first sub-portion.

In some embodiments, a thickness of the first sub-portion is greater than or equal to a thickness of the second sub-portion.

In some embodiments, a dimension of the second sub-portion in a first direction is greater than or equal to 0.3 μm. The first direction is perpendicular to a boundary where orthogonal projections of the first sub-portion and the second sub-portion on the base substrate are adjacently connected in an orthogonal projection of the first region on the base substrate.

In some embodiments, the first via hole includes a first sidewall and a second sidewall; the first sidewall is located in the first insulating layer, and an end of the first sidewall away from the base substrate is connected to the first semiconductor pattern; at least part of the second sidewall is located in the second insulating layer; and a slope angle of the first sidewall is greater than a slope angle of the second sidewall.

In some embodiments, the slope angle of the first sidewall is in a range of 60° to 90°, and/or the slope angle of the second sidewall is in a range of 30° to 60°.

In some embodiments, the array substrate further includes a second via hole, a second connection electrode, a third insulating layer, a third via hole and a first electrode. The second via hole penetrates through the second insulating layer and exposes at least part of the second region. The second connection electrode is disposed on the side of the second insulating layer away from the base substrate and at least partially located in the second via hole, and the second connection electrode is connected to the second region in the second via hole. The third insulating layer is disposed on a side of the second connection electrode away from the base substrate. The third via hole penetrates through the third insulating layer and exposes at least part of the second connection electrode. The first electrode is at least partially located in the third via hole, and the first electrode is connected to the second connection electrode in the third via hole.

In some embodiments, the second connection electrode and the first gate include a same material and are arranged in a same layer; and at least part of edges of the second connection electrode is in contact with the second region.

In some embodiments, the second region includes a third sub-portion and a fourth sub-portion located in the second via hole; the third sub-portion is in contact with the second connection electrode; the fourth sub-portion is adjacently connected to an edge of the second connection electrode; orthogonal projections of the fourth sub-portion and the second connection electrode on the base substrate do not overlap; and a conductivity of the fourth sub-portion is greater than a conductivity of the third sub-portion.

In some embodiments, a thickness of the third sub-portion is greater than or equal to a thickness of the fourth sub-portion.

In some embodiments, a dimension of the fourth sub-portion in a second direction is greater than or equal to 0.3 μm; and the second direction is perpendicular to a boundary where orthogonal projections of the third sub-portion and the fourth sub-portion on the base substrate are adjacently connected in an orthogonal projection of the second region on the base substrate.

In some embodiments, orthogonal projections of the second via hole and the third via hole on the base substrate partially overlap.

In some embodiments, the third insulating layer includes a passivation layer and a planarization layer that are stacked in a direction away from the base substrate; the third via hole includes a first sub-hole penetrating through the passivation layer and a second sub-hole penetrating through the planarization layer; an orthogonal projection of the first sub-hole on the base substrate is located within an orthogonal projection of the second sub-hole on the base substrate; and an overlapping area of the orthogonal projection of the first sub-hole on the base substrate and an orthogonal projection of the second via hole on the base substrate is smaller than an overlapping area of the orthogonal projection of the second sub-hole on the base substrate and the orthogonal projection of the second via hole on the base substrate.

In some embodiments, the orthogonal projection of the second sub-hole on the base substrate includes a first border located within the orthogonal projection of the second via hole on the base substrate; and a distance between the first border and a border of the orthogonal projection of the second via hole on the base substrate is greater than or equal to 0.5 μm.

In some embodiments, the second insulating layer is disposed between the first semiconductor pattern and the first gate, and the second insulating layer includes a first pattern in contact with the first gate. An orthogonal projection of the first pattern on the base substrate covers an orthogonal projection of the first gate on the base substrate; and a distance between a border of the orthogonal projection of the first pattern on the base substrate and a border of the orthogonal projection of the first gate on the base substrate is in a range of 0.3 μm to 1.5 μm.

In some embodiments, an angle between a sidewall of the first gate and a plane where the base substrate is located is in a range of 30° to 80°.

In some embodiments, the second transistor further includes a source and a drain, and the source and the drain as well as the second gate include a same material and are arranged in a same layer.

In some embodiments, the second semiconductor pattern includes a second channel region, and a third region and a fourth region that are respectively located on two sides of the second channel region The array substrate further includes a second insulating layer, a fourth via hole and a fifth via hole. The second insulating layer is disposed between the second semiconductor pattern and the second gate. The fourth via hole penetrates through the second insulating layer and exposes at least part of the third region. The fifth via hole penetrates through the second insulating layer and exposes at least part of the fourth region. At least part of the source is located in the fourth via hole and is connected to the third region through the fourth via hole; at least part of edges of the source is in contact with the third region; at least part of the drain is located in the fifth via hole and is connected to the fourth region through the fifth via hole; and at least part of edges of the drain is in contact with the fourth region.

In some embodiments, at least part of edges of the source and at least part of edges of the drain are in contact with the second semiconductor pattern.

In some embodiments, the third region includes a fifth sub-portion and a sixth sub-portion located in the fourth via hole; the fifth sub-portion is in contact with the source; the sixth sub-portion is adjacently connected to an edge of the source; orthogonal projections of the sixth sub-portion and the source on the base substrate do not overlap; a conductivity of the sixth sub-portion is greater than a conductivity of the fifth sub-portion. The fourth region includes a seventh sub-portion and an eighth sub-portion located in the fifth via hole; the seventh sub-portion is in contact with the drain; the eighth sub-portion is adjacently connected to an edge of the drain; orthogonal projections of the eighth sub-portion and the drain on the base substrate do not overlap; and a conductivity of the eighth sub-portion is greater than a conductivity of the seventh sub-portion.

In some embodiments, a dimension of the sixth sub-portion in a third direction is greater than or equal to 0.3 μm, the third direction being perpendicular to a boundary where orthogonal projections of the fifth sub-portion and the sixth sub-portion on the base substrate are adjacently connected in an orthogonal projection of the third region on the base substrate; and/or, a dimension of the eighth sub-portion in a fourth direction is greater than or equal to 0.3 μm, the fourth direction being perpendicular to a boundary where orthogonal projections of the seventh sub-portion and the eighth sub-portion on the base substrate are adjacently connected in an orthogonal projection of the fourth region on the base substrate.

In some embodiments, a thickness of the fifth sub-portion is greater than or equal to a thickness of the sixth sub-portion; and/or a thickness of the seventh sub-portion is greater than or equal to a thickness of the eighth sub-portion.

In some embodiments, a thickness difference between the sixth sub-portion and the fifth sub-portion is in a range of 10 Å to 500 Å; and/or a thickness difference between the eighth sub-portion and the seventh sub-portion is in a range of 10 Å to 500 Å.

In some embodiments, the second transistor further includes a third gate. The third gate is disposed on a side of the second semiconductor pattern close to the base substrate, an orthogonal projection of the third gate on the base substrate covers an orthogonal projection of the second gate on the base substrate, and the third gate is electrically connected to the second gate.

In some embodiments, the array substrate further includes a first insulating layer, a second insulating layer, and a passivation layer, a planarization layer, a first electrode, a fourth insulating layer, and a second electrode that are sequentially arranged in the direction away from the base substrate. The first insulating layer is located between the first signal line and the first semiconductor pattern and includes a first material layer and a second material layer that are stacked in a direction away from the base substrate, and a material of the first material layer includes silicon nitride, and a material of the second material layer includes silicon oxide. The second insulating layer is located between the first semiconductor pattern and the first gate, and a material of the second insulating layer includes silicon oxide. The passivation layer includes a third material layer and a fourth material layer that are stacked in the direction away from the base substrate, a material of the third material layer includes silicon oxide, a material of the fourth material layer includes silicon nitride, and a material of the fourth insulating layer includes silicon nitride.

In some embodiments, an atomic ratio of silicon to nitrogen in the silicon nitride of the first material layer is in a range of 1:1 to 1:0.5; an atomic ratio of silicon to oxygen in the silicon oxide of the second material layer is in a range of 1:1 to 1:2; an atomic ratio of silicon to oxygen in the silicon oxide of the second insulating layer is in a range of 1:1 to 1:2; an atomic ratio of silicon to oxygen in the silicon oxide of the third material layer is in a range of 1:1.5 to 1:2; an atomic ratio of silicon to nitrogen in the silicon nitride of the fourth material layer is in a range of 1:1 to 1:0.6; and an atomic ratio of silicon to nitrogen in the silicon nitride of the fourth insulating layer is in a range of 1:1 to 1:0.6.

In another aspect, a display panel is provided. The display panel includes the array substrate as described in any one of the above embodiments, a color filter substrate, and a liquid crystal layer. The color filter substrate is arranged opposite to the array substrate. The liquid crystal layer is disposed between the array substrate and the color filter substrate.

In another aspect, a display device is provided. The display device includes the display panel as described above.

### BRIEF DESCRIPTION OF THE DRAWINGS

In order to describe technical solutions in some embodiments of the present disclosure more clearly, the accompanying drawings to be used in some embodiments of the present disclosure will be introduced briefly. However, the accompanying drawings to be described below are merely some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a structural diagram of a display device, in accordance with some embodiments;

FIG. 2 is a diagram showing a structure of a composition of a display panel, in accordance with some embodiments;

FIG. 3 is a sectional view showing a structure of an array substrate, in accordance with some embodiments;

FIG. 4 is a sectional view showing a structure of an array substrate, in accordance with some other embodiments;

FIG. 5 is a plan view showing a partial structure of a display region, in accordance with some embodiments;

FIG. 6 is a sectional view taken along the section line A-A in FIG. 5;

FIG. 7 is another sectional view taken along the section line A-A in FIG. 5;

FIG. 8 is a plan view showing a partial structure at a first connection electrode, in accordance with some embodiments;

FIG. 9 is a sectional view showing a partial structure at a first connection electrode, in accordance with some embodiments;

FIG. 10 is a plan view showing a partial structure at a second connection electrode, in accordance with some embodiments;

FIG. 11 is a structural diagram of a first gate, in accordance with some embodiments;

FIG. 12 is a plan view showing a structure of a first transistor, in accordance with some embodiments; and

FIG. 13 is a plan view showing a structure of a first transistor, in accordance with some other embodiments.

### DETAILED DESCRIPTION

The technical solutions in some embodiments of the present disclosure will be described clearly and completely with reference to the accompanying drawings. However, the described embodiments are merely some but not all embodiments of the present disclosure. All other embodiments obtained by a person of ordinary skill in the art based on embodiments of the present disclosure shall be included in the protection scope of the present disclosure.

Unless the context requires otherwise, throughout the specification and the claims, the term “comprise” and other forms thereof such as the third-person singular form “comprises” and the present participle form “comprising” are construed as an open and inclusive meaning, i.e., “including, but not limited to”. In the description of the specification, the terms such as “one embodiment,” “some embodiments,” “exemplary embodiments,” “example,” “specific example,” or “some examples” are intended to indicate that specific features, structures, materials, or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics described may be included in any one or more embodiments or examples in any suitable manner.

In the present disclosure, terms such as “lower”, “below”, “above” and “upper” and the like are used to explain the relational association of components shown in the drawings. The terms may be relative concepts and described based on the directions shown in the drawings, or may be described based on the order in which the process steps are formed, but are not limited thereto.

It will be understood that, when a layer or element is referred to as being on another layer or substrate, it may be that the layer or element is directly on the another layer or substrate, or it may be that intermediate layer(s) exist between the layer or element and the another layer or substrate.

The term “opposed to” means that a first element may be directly or indirectly opposed to a second element. In a case where a third element is disposed between the first element and the second element, the first element and the second element may be understood as being indirectly opposite to each other although still opposite to each other.

The terms “first” and “second” are used for descriptive purposes only, and are not to be construed as indicating or implying a relative importance or implicitly indicating the number of indicated technical features. Thus, features defined with “first” or “second” may explicitly or implicitly include one or more of the features. In the description of the embodiments of the present disclosure, the term “multiple”, “a plurality of” or “the plurality of” means two or more unless otherwise specified.

In the description of some embodiments, terms such as “coupled” and “connected” and their derivatives may be used. The term “connected” should be understood in a broad sense. For example, the term “connected” may represent a fixed connection, or a detachable connection, or a one-piece connection; alternatively, the term “connected” may represent a direct connection, or an indirect connection through an intermediate medium. For example, the term “coupled” indicates that two or more components are in direct physical or electrical contact. The term “coupled” or “communicatively coupled” may also mean that two or more components are not in direct contact with each other but still cooperate or interact with each other. The embodiments disclosed herein are not necessarily limited to the content herein.

The phrase “at least one of A, B, and C” has the same meaning as the phrase “at least one of A, B, or C”, both including the following combinations of A, B, and C: only A, only B, only C, a combination of A and B, a combination of A and C, a combination of B and C, and a combination of A, B, and C.

The phrase “A and/or B” includes the following three combinations: only A, only B, and a combination of A and B.

As used herein, the term “if” is, optionally, construed as “when” or “in a case where” or “in response to determining that” or “in response to detecting,” depending on the context. Similarly, depending on the context, the phrase “if it is determined that” or “if [a stated condition or event] is detected” is optionally construed as “in a case where it is determined that” or “in response to determining that” or “in a case where [the stated condition or event] is detected” or “in response to detecting [the stated condition or event].”

The phrase “applicable to” or “configured to” used herein has an open and inclusive meaning, which does not exclude devices that are applicable to or configured to perform additional tasks or steps.

In addition, the phrase “based on” used is meant to be open and inclusive, since a process, step, calculation or other action that is “based on” one or more of the stated conditions or values may, in practice, be based on additional conditions or value exceeding those stated.

The term such as “about,” “substantially,” or “approximately” as used herein includes a stated value and an average value within an acceptable range of deviation of a particular value determined by a person of ordinary skill in the art, considering measurement in question and errors associated with measurement of a particular quantity (i.e., limitations of a measurement system).

The term such as “parallel,” “perpendicular,” or “equal” as used herein includes a stated condition and a condition similar to the stated condition. A range of the similar condition is within an acceptable deviation range, and the acceptable deviation range is determined by a person of ordinary skill in the art, considering measurement in question and errors associated with measurement of a particular quantity (i.e., the limitations of a measurement system). For example, the term “parallel” includes absolute parallelism and approximate parallelism, and an acceptable range of deviation of the approximate parallelism may be, for example, a deviation within 5°; the term “perpendicular” includes absolute perpendicularity and approximate perpendicularity, and an acceptable range of deviation of the approximate perpendicularity may also be, for example, a deviation within 5°; and the term “equal” includes absolute equality and approximate equality, and an acceptable range of deviation of the approximate equality may be that, for example, a difference between the two that are equal is less than or equal to 5% of either of the two.

It will be understood that, when a layer or element is referred to as being on another layer or substrate, it may be that the layer or element is directly on the another layer or substrate, or it may be that intermediate layer(s) exist between the layer or element and the another layer or substrate.

Exemplary embodiments are described herein with reference to sectional views and/or plan views that are schematic illustrations of idealized embodiments. In the accompanying drawings, thicknesses of layers and sizes of regions are enlarged for clarity. Variations in shape with respect to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown to have a rectangular shape generally has a feature being curved. Therefore, the regions shown in the accompanying drawings are schematic in nature, and their shapes are not intended to show actual shapes of the regions in a device, and are not intended to limit the scope of the exemplary embodiments.

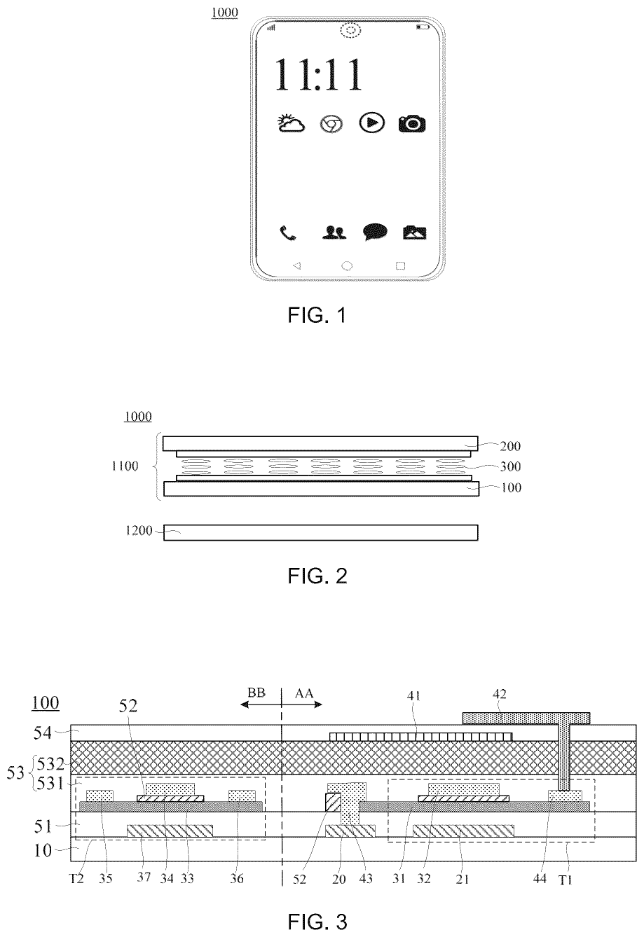

Referring to FIG. 1, embodiments of the present disclosure provide a display device 1000. The display device 1000 is a product having a function of displaying images. For example, the display device 1000 may be any device that displays images whether in motion (e.g., videos) or stationary (e.g., static images), and whether textual or graphical.

For example, the display device 1000 may be any product or component that has a display function, such as a television, a notebook computer, a tablet computer, a personal digital assistant (PDA), a mobile phone (cell phone), a watch, a clock, a calculator, a GPS receiver/navigator, a camera, a display in a camera view (e.g., a display of a rear camera in a vehicle), a wearable device, an augmented reality (AR) device, a virtual reality (VR) device, a mixed reality (MR) device, a vehicle-mounted display, or a flight display.

In some embodiments, the display device 1000 may be a liquid crystal display (LCD) device from the perspective of the light emission type of the display device 1000. The display device 1000 may be a flat display device or a curved display device from the perspective of the form of the display device 1000. The display device 1000 may have a rectangular or circular shape from the perspective of the shape of the display device 1000. Some embodiments of the present disclosure will be schematically described below by taking an example in which the display device is a rectangular flat liquid crystal display device. However, the embodiments of the present disclosure are not limited thereto, and any other display devices may also be taken into consideration as long as the same technical concept is applied.

In some embodiments, the display device 1000 includes a display panel 1100 and a driver circuit board. The driver circuit board may include driving circuits such as a timing controller (TCON), a power supply management chip DC/DC, and an adjustable resistor voltage divider circuit (for generating Vcom). The driver circuit board may also include other circuit structures, which will not be listed here. The driver circuit board is electrically connected to the display panel 1100 and is used for transmitting control signals to the display panel 1100, thereby driving the display panel 1100 to display images. In addition, the display device 1000 may further include a touch structure, an under-display camera and an under-display fingerprint recognition sensor, so that the display device 1000 can realize various different functions such as touching, photographing, video recording, or fingerprint recognition, which will not be specifically described here.

In the case where the display device 1000 is the liquid crystal display device, referring to FIG. 2, the display device 1000 may further include a backlight source 1200 disposed on a back side of the display panel 1100. For example, the backlight source 1200 may be a direct-lit backlight source or an edge-lit backlight source. The backlight source 1200 is used to provide a light source for the display panel 1100. The display panel 1100 includes a plurality of sub-pixels, and each sub-pixel can adjust an amount of light that passes through the display panel 1100 and is located within the sub-pixel, so that all sub-pixel display the same gray level or different gray levels to achieve the purpose of image display.

With continued reference to FIG. 2, in a case where the display panel 1100 is a liquid crystal display panel, the display panel 1100 may include: an array substrate 100 and a color filter substrate 200 (also referred to as an opposite substrate or an encapsulation substrate) that are opposite to each other, and a liquid crystal layer 300 disposed between the array substrate 100 and the color filter substrate 200. The color filter substrate 200 can filter light incident on the color filter substrate 200 so that each sub-pixel emits light of a single color (such as red, green or blue), and different sub-pixels can emit light of the same or different colors, thereby realizing color display of the display panel 1100. Of course, the display panel 1100 may also include other structures as long as the same technical concept is adopted. For example, the display panel 1100 may further include: a first alignment film (not shown in the figure) disposed on a side of the array substrate 100 close to the liquid crystal layer 300, and a second alignment film (not shown in the figure) disposed on a side of the opposite substrate close to the liquid crystal layer 300.

Referring to FIG. 3, the array substrate 100 may include a display region AA and a peripheral region BB surrounding the display region AA. The display region AA may include a plurality of pixel circuits, a plurality of signal lines (e.g., first signal line(s) 20, scan signal lines, etc.), first electrode(s) (e.g., common electrode(s)) 41 and second electrode(s) (e.g., pixel electrode(s)) 42. The peripheral region BB may include, for example, a gate driving circuit (Gate Driver On Array (GOA)). The pixel circuit may include, for example, a first transistor T1. In the embodiments of the present disclosure, one of the first electrode 41 and the second electrode 42 is configured to form a pixel electrode, and another of the first electrode 41 and the second electrode 42 is configured to form a common electrode. The pixel electrode is configured to be electrically connected to a first signal line, and the common electrode is configured to be electrically connected to a common voltage signal terminal (constant voltage signal terminal).

For example, as shown in FIG. 3, the first electrode 41 is configured to form the common electrode, and the second electrode 42 is configured to form the pixel electrode. In this case, the pixel circuit (the first transistor T1) may be connected to the first signal line 20 and the second electrode 42, and is configured to transmit a data signal to the second electrode 42 through the first signal line 20. The second electrode 42 creates an electric field with the first electrode 41 due to the above data signal, and the electric field drives liquid crystal molecules in the liquid crystal layer to rotate, to realize control of different gray levels.

In the related art, in the display region, the signal line (such as the data signal line) is usually disposed on a side of the transistor (the transistor included in the pixel circuit) away from the base substrate, and each of the pixel electrode and the common electrode has a small distance from the signal line. A parasitic capacitance is easily created between the signal line and each of the pixel electrode and the common electrode. As a result, the load on the signal line is increased, the charging efficiency of the first electrode is reduced, which is not conducive to reducing the power consumption of the array substrate.

In order to solve the above technical problem, referring to FIG. 3, embodiments of the present disclosure provide an array substrate 100, including a base substrate 10, a first signal line 20, a first transistor T1, a second transistor T2, a first electrode 41, and a second electrode 42. The first signal line 20 is disposed on the base substrate 10 and at least partially located in the display region AA. The first transistor T1 is located in the display region AA, and is disposed on a side of the first signal line 20 away from the base substrate 10.

In the embodiments of the present disclosure, the first transistor T1 is disposed on the side of the first signal line 20 away from the base substrate 10. That is, the first signal line 20 is arranged on a side of the first transistor T1 close to the base substrate 10. In this way, it is conducive to increasing the distance between the first signal line 20 and each of the first electrode 41 and the second electrode 42. The parasitic capacitance between the first signal line 20 and each of the first electrode 41 and the second electrode 42 is reduced, which is conducive to reducing the load on the first signal line 20 and improving the charging efficiency of the first electrode 41. In addition, it is conducive to improving the pixel density and refresh rate of the array substrate 100, as well as reducing the power consumption of the first signal line 20 and reducing the overall power consumption of the array substrate 100.

For example, the base substrate 10 may be made of a rigid material such as glass, to improve the bearing capacity of the base substrate 10 for other film layers thereon. Alternatively, the base substrate 10 may be made of a flexible material such as polyimide (PI), to improve the bending resistance and stretching resistance of the whole metal oxide thin film transistor, and avoid open circuits caused by the crack of the base substrate 10 due to the stress generated during bending, stretching, and twisting. In practical applications, the material of the base substrate 10 can be selected according to actual needs to ensure that the metal oxide thin film transistor has good performance.

The first signal line 20 may be, for example, a data signal line. In this case, the first signal line 20 may be configured to transmit a data signal to the pixel electrode. Of course, in some other embodiments, the first signal line 20 may be used to transmit other signal, as long as the same technical concept is adopted.

For example, a material of the first signal line 20 may include a conductive material, and the conductive material may include a metal material, such as one or more of titanium, aluminum, copper, molybdenum, niobium, nickel, and alloys thereof. Alternatively, the first signal line 20 may be of a metal stacked structure. For example, the first signal line 20 may include one of a titanium-aluminum-titanium (Ti/Al/Ti) stacked structure, a molybdenum-aluminum (Mo/Al) stacked structure, a molybdenum-aluminum-molybdenum (Mo/Al/Mo) stacked structure, a molybdenum-niobium-titanium (MoNb/Ti) stacked structure, a molybdenum-niobium-titanium-copper (MoNb/Ti/Cu) stacked structure, a molybdenum-niobium-copper-molybdenum-nickel-titanium (MoNb/Cu/MTD) stacked structure, a molybdenum-neodymium-copper stacked structure, a MoNb-copper-MoNb stacked structure, and an AlNb-molybdenum-AlNd stacked structure. Of course, the embodiments of the present disclosure are not limited thereto, and the first signal line 20 may also be made of any other suitable metal or metal stacked structure. In addition, a thickness of the first signal line 20 may be in a range of 1500 angstroms (1 angstrom=10-10 m) to 8000 angstroms. For example, the thickness of the first signal line 20 may be 1500 angstroms, 2000 angstroms, 5500 angstroms, or 8000 angstroms, which will not be listed one by one in the embodiments of the present disclosure.

With continued reference to FIG. 3, the first transistor T1 refers to a transistor disposed in the display region AA. For example, the first transistor T1 is a transistor for constituting a pixel circuit. The first transistor T1 includes a first semiconductor pattern 31 and a first gate 32 disposed on a side of the first semiconductor pattern 31 away from the base substrate 10. That is, the first transistor T1 is a top-gate transistor. The second transistor T2 refers to a transistor disposed in the peripheral region BB. For example, the second transistor T2 may be a transistor for constituting a gate driving circuit. The second transistor T2 includes a second semiconductor pattern 33 and a second gate 34 disposed on a side of the second semiconductor pattern 33 away from the base substrate 10. That is, the second transistor T2 is also a top-gate transistor. The first gate 32 and the second gate 34 are arranged in the same layer, so that the first gate 32 and the second gate 34 may be formed using the same mask and/or the same material in the same patterning process, which is conducive to simplifying the manufacturing process of the array substrate and in turn reducing the manufacturing cost of the array substrate.

In some embodiments, the first semiconductor pattern 31 and the second semiconductor pattern 33 may be formed using various suitable semiconductor materials and various suitable manufacturing methods. In other words, the materials of the first semiconductor pattern 31 and the second semiconductor pattern 33 may each include at least one of various suitable semiconductor materials. In some embodiments, the semiconductor material includes M1OaNb, where M1 is a single metal or a combination of multiple metals, a >0, b ≥0, O represents oxygen, and N represents nitrogen. That is, the semiconductor material is a metal oxide material or a metal oxynitride material. Suitable metal oxide materials include, but are not limited to, one or more of indium gallium zinc oxide (IGZO), indium gallium tin oxide (IGTO), indium tin zinc oxide (ITZO), indium gallium oxide (IGO), indium gallium zinc tin oxide (IGZTO), indium zinc oxide (IZO), zinc tin oxide (ZTO), indium-free metal oxide (In-free OS), rare earth-doped oxide (Ln—OS, e.g., rare earth element-doped IGZO/IZO), zinc oxide (ZnO), gallium oxide (GaO), indium oxide (InO), HfInZnO (HIZO), ZnO:F, In₂O₃:Sn, In₂O₃:Mo, Cd2SnO₄, ZnO:Al, TiO₂:Nb and Cd—Sn—O. Suitable metal oxynitride materials include, but are not limited to, zinc oxynitride, indium oxynitride, gallium oxynitride, tin oxynitride, cadmium oxynitride, aluminum oxynitride, germanium oxynitride, titanium oxynitride, silicon oxynitride, or combinations thereof. In addition, the material of the first semiconductor pattern 31 may be in an amorphous, partially crystalline, single-crystalline or polycrystalline state, and may also be a single-layer or multi-layer structure.

In some embodiments, the first semiconductor pattern 31 may be made of a high-mobility metal oxide semiconductor (HMOS) material. In this way, it is conducive to improving the electron mobility of the first semiconductor pattern 31 and increasing the on-state current of the first transistor T1. In addition, the high-mobility metal oxide semiconductor material also has good stability under illumination, which is conducive to improving the stability of the first transistor T1 under illumination. High-mobility metal oxide semiconductor materials include, but are not limited to, IZO doped with an rare earth element, and IGZO doped with an rare earth element, and the doping concentration of the rare earth element is in a range of 0.1% to 2%.

For example, the first gate 32 and the second gate 34 may also include the same conductive material. For example, the first gate and the second gate 34 may each be a metal stacked structure. As for the metal stacked structure, reference can be made to the above metal stacked structure of the first signal line 20, and details will not be repeated here. The materials of the first gate 32 and the second gate 34 may be the same as the material of the first signal line 20, or the materials of the first gate 32 and the second gate 34 may be different from the material of the first signal line 20. In addition, the thicknesses of the first gate 32 and the second gate 34 may each be in a range of 1500 Å to 8000 Å. For example, the thicknesses of the first gate 32 and the second gate 34 may each be 1500 Å, 2000 Å, 4500 Å, 6000 Å or 8000 Å, which will not be listed one by one in the embodiments of the present disclosure.

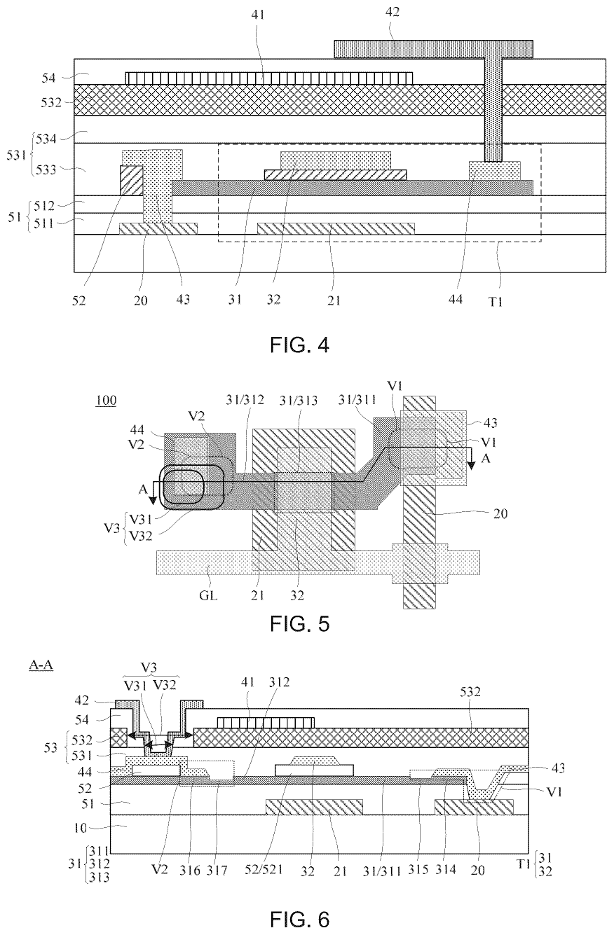

In some embodiments, referring to FIGS. 3 and 4, the array substrate 100 may further include a first insulating layer 51, a second insulating layer 52, a third insulating layer 53, a fourth insulating layer 54, the first electrode 41, and the second electrode 42.

The first insulating layer 51 is disposed between the first signal line(s) 20 and the first semiconductor pattern 31. For example, the first insulating layer 51 may also be a buffer layer. The second insulating layer 52 is disposed on a side of the first semiconductor pattern 31 away from the base substrate 10. For example, the second insulating layer 52 may be located between the first semiconductor pattern 31 and the first gate 32. In this case, the second insulating layer 52 may also be a gate insulating layer GI. The third insulating layer 53 may include a passivation layer 531 and a planarization layer 532 that are stacked in a direction away from the base substrate 10. The first electrode 41 is located between the third insulating layer 53 and the fourth insulating layer 54, and the second electrode 42 is located on a side of the fourth insulating layer 54 away from the base substrate 10.

Referring to FIGS. 3 and 4, the first insulating layer 51 may include a first material layer 511 and a second material layer 512 that are stacked in the direction away from the base substrate 10. A material of the first material layer 511 includes silicon nitride (SixNy), and a material of the second material layer 512 includes silicon oxide (SixOy). The second insulating layer 52 is located between the first semiconductor pattern 31 and the first gate 32, and a material of the second insulating layer 52 includes silicon oxide (SixOy). The passivation layer 531 includes a third material layer 533 and a fourth material layer 534 that are stacked in the direction away from the base substrate 10. A material of the third material layer 533 includes silicon oxide (SixOy), and a material of the fourth material layer 534 includes silicon nitride (SixNy). A material of the fourth insulating layer 54 includes silicon nitride (SixNy). In a case where different film layers mentioned above include the same material, the material (e.g., SixOy or SixNy) may take the same or different values of “x” and the same or different values of “y”.

In some embodiments, when the material of the first semiconductor pattern 31 is a high mobility metal oxide semiconductor (HMOS) material, an atomic ratio of silicon to nitrogen in the silicon nitride (SixNy) of the first material layer 511 is in a range of 1:1 to 1:0.5. An atomic ratio of silicon to oxygen in the silicon oxide (SixOy) of the second material layer 512 is in a range of 1:1 to 1:2. An atomic ratio of silicon to oxygen in the silicon oxide (SixOy) of the second insulating layer 52 is in a range of 1:1 to 1:2. An atomic ratio of silicon to oxygen in the silicon oxide (SixOy) of the third material layer 533 is in a range of 1:1.5 to 1:2. An atomic ratio of silicon to nitrogen in the silicon nitride (SixNy) of the fourth material layer 534 is in a range of 1:1 to 1:0.6. An atomic ratio of silicon to nitrogen in the silicon nitride (SixNy) of the fourth insulating layer 54 is in a range of 1:1 to 1:0.6. In this way, it is conducive to improving the structural stability of the first semiconductor pattern 31. On this basis, the first semiconductor pattern 31 may be made of a HMOS material, and the second semiconductor pattern 33 may be made of a HMOS material.

In some embodiments, referring to FIGS. 5, 6, and 7, the first semiconductor pattern 31 includes a first channel region 313, and a first region 311 and a second region 312 that are respectively located on two sides of the first channel region 313. The first channel region 313 is configured to form a channel structure of the first transistor T1. One of the first region 311 and the second region 312 is configured to form a source (or a source connection region) of the first transistor T1, and another of the first region 311 and the second region 312 is configured to form a drain (or a drain connection region) of the first transistor T1. Moreover, the one of the first region 311 and the second region 312 is configured to be electrically connected to the first signal line 20, and the another of the first region 311 and the second region 312 is configured to be electrically connected to the first electrode (e.g., the pixel electrode). For example, the first region 311 is configured to be electrically connected to the first signal line 20, and the second region 312 is configured to be electrically connected to the first electrode 41.

With continued reference to FIGS. 5, 6 and 7, the array substrate 100 further includes the first insulating layer 51, the second insulating layer 52, first via hole(s) V1 and first connection electrode(s) 43.

The first via hole V1 penetrates through at least the first insulating layer 51 and the second insulating layer 52, and exposes at least part of the first signal line 20 and at least part of the first region 311. The first connection electrode 43 is disposed on a side of the second insulating layer 52 away from the base substrate 10. The first connection electrode 43 is electrically connected to the first signal line 20 and the first region 311 in the first via hole V1. That is, the first region 311 is electrically connected to the first signal line 20 through the first connection electrode 43.

Compared with a case in which the first region 311 is directly electrically connected to the first signal line 20 through a via hole (at least part of the first region 311 is located in the via hole and is in direct contact with the first signal line 20), the first region 311 is electrically connected to the first signal line 20 through the first connection electrode 43, which is conducive to reducing the morphological fluctuation of the first region 311 in a direction perpendicular to the base substrate 10. Therefore, the thickness uniformity of the first region 311 is improved, the risk of local fracture or excessive local thickness of the first region 311 is reduced, and it is conducive to improving the reliability of the first transistor T1.

In some embodiments, the first connection electrode 43 and one of the first gate 32, the first electrode 41 and the second electrode 42 may include the same material, and may be arranged in the same layer. Compared with a case in which the first connection electrode 43 is formed using an additional film layer and process, the first connection electrode 43 and one of the first gate 32, the first electrode 41 and the second electrode 42 include the same material and are arranged in the same layer, which is conducive to simplifying the manufacturing process of the array substrate 100 and reducing the manufacturing cost of the array substrate 100.

In some embodiments, as shown in FIG. 6, the first connection electrode 43 and the first gate 32 include the same material and are arranged in the same layer. For example, the first connection electrode 43 and the first gate 32 are formed using the same mask and/or the same material during the same patterning process. For example, a film layer where the first connection electrode 43 and the first gate 32 are located is a gate conductive layer.

Referring to FIGS. 5 and 6, in the case where the first connection electrode 43 and the first gate 32 are arranged in the same layer, at least part of edges of the first connection electrode 43 is in contact with the first region 311. In this way, the connection resistance between the first connection electrode 43 and the first region 311 may be reduced, and the connection reliability between the first connection electrode 43 and the first region 311 may be improved. For example, as shown in FIGS. 5 and 6, an edge of the first connection electrode 43 close to the first channel region 313 is in contact with the first region 311.

The first transistor T1 is a top-gate transistor. A manufacturing process of the array substrate shown in FIG. 6 includes: forming the first semiconductor pattern 31 on the base substrate 10; forming the second insulating layer 52; forming the gate conductive layer; and performing a conductorization process on the first semiconductor pattern 31 using the gate conductive layer as a mask. In the case where the first connection electrode 43 and the first gate 32 are arranged in the same layer, during the process of performing a conductorization process on the first semiconductor pattern using the gate conductive layer as a mask, a portion of the first region 311 covered by the first connection electrode 43 is not subjected to the conductorization process and has poor conductivity, and a portion of the first region 311 not blocked by the first connection electrode 43 is doped to form a conductor and its resistance is reduced. At least part of edges of the first connection electrode 43 is in contact with the first region 311, so that a part of edges of the first connection electrode 43 in contact with the first region 311 may be in contact with the conductorized portion of the first region 311 to reduce the connection resistance (contact resistance) between the first connection electrode 43 and the first region 311.

In some other embodiments, in the case where the first connection electrode and the first electrode or the second electrode include the same material and are arranged in the same layer, an edge of the first connection electrode may be in contact with the first region, or the edge of the first connection electrode may not be in contact with the first region. For example, in the case where the first connection electrode and the first electrode are arranged in the same layer, all edges of the first connection electrode may be located on the third insulating layer; alternatively, part of the edges of the first connection electrode is located on the third insulating layer, and part of the edges of the first connection electrode is in contact with the first region 311.

In the case where the first connection electrode and the first electrode or the second electrode include the same material and are arranged in the same layer, during the process of performing a conductorization process on the first semiconductor pattern using the gate conductive layer as a mask, the first connection electrode has not yet been formed, so that the first connection electrode will not block the first semiconductor pattern. The entire first region may be subjected to the conductorization process, and the first region can be considered to be entirely a conductor. In this case, electrical connection can be realized as long as the first connection electrode is in contact with the first region, and the first connection electrode and the first region have a small connection resistance.

In some embodiments, referring to FIGS. 8 and 9, the first connection electrode 43 and the first gate electrode 32 include the same material and are arranged in the same layer. The first region 311 includes a first sub-portion 314 and a second sub-portion 315 that are located in the first via hole V1. The first sub-portion 314 is in contact with the first connection electrode 43. The second sub-portion 315 is adjacently connected to an edge of the first connection electrode 43. Orthogonal projections of the second sub-portion 315 and the first connection electrode 43 on the base substrate 10 do not overlap. The conductivity of the second sub-portion 315 is greater than the conductivity of the first sub-portion 314. In this way, it is conducive to reducing the connection resistance between the edge of the first connection electrode 43 and the second sub-portion 315.

For example, the first sub-portion 314 and the second sub-portion 315 include the same semiconductor material, and the first sub-portion 314 and the second sub-portion 315 are different in that the second sub-portion 315 is subjected to a process (e.g., a doping process) to make it conductive. During the doping process, the first semiconductor pattern 31 is doped using the first gate 32 and the first connection electrode 43 as a mask. The first sub-portion 314 is in contact with the first connection electrode 43, and is located on a side of the first connection electrode 43 close to the base substrate 10. The dopant ions are blocked by the first connection electrode 43, so that the first sub-portion 314 is not subjected to the doping process. The orthogonal projection of the second sub-portion 315 on the base substrate 10 does not overlap with the orthogonal projection of the first connection electrode 43 on the base substrate 10. That is, the first connection electrode 43 does not block the second sub-portion 315. In this case, the second sub-portion 315 can be subjected to the doping process and therefore become more conductive (compared to the first sub-portion 314).

In some embodiments, referring to FIGS. 8 and 9, a thickness H1 of the first sub-portion 314 is greater than or equal to a thickness H2 of the second sub-portion 315. In other words, a portion (the second sub-portion 315) in the first via hole V1 not covered by the first connection electrode 43 has a smaller thickness and is recessed toward a side close to the base substrate 10 to form a groove. For example, the thickness of the first sub-portion 314 is greater than the thickness of the second sub-portion 315.

For example, a thickness difference ΔH (i.e., H1−H2) between the first sub-portion 314 and the second sub-portion 315 may be in a range of 10 Å to 500 Å. For example, the thickness difference AH between the first sub-portion 314 and the second sub-portion 315 may be in a range of 10 Å to 250 Å; alternatively, the thickness difference ΔH between the first sub-portion 314 and the second sub-portion 315 may be in a range of 250 Å to 500 Å. For example, the thickness difference ΔH between the first sub-portion 314 and the second sub-portion 315 may be 10 Å, 100 Å, 200 Å, 250 Å, 350 Å, 400 Å or 500 Å, which will not be listed one by one in the embodiments of the present disclosure.

The manufacturing process of the array substrate may include as follows. The first signal line, the first insulating layer, the first semiconductor pattern and the second insulating layer are sequentially formed on the base substrate, and the first via hole penetrating through the first insulating layer and the second insulating layer is formed; the first via hole exposes part of the first signal line and part of the first region; in this case, the first via hole includes a portion located in the first insulating layer and a portion located in the second insulating layer. Then, the first gate and the first connection electrode (the gate conductive layer) are formed on a side of the second insulating layer away from the base substrate; at least part of the first connection electrode is located in the first via hole, and the first connection electrode only covers a part of the first via hole; in other words, the first connection electrode also exposes a part of the first via hole, so that at least part of edges of the first connection electrode can be in contact with the first region through the first via hole. Next, the second insulating layer is patterned using the gate conductive layer as a mask; in a case where the first connection electrode exposes a part of the first via hole, for the portion of the first via hole located in the second insulating layer, only a part that is covered by the first connection electrode will be retained, and a part that is not covered by the first connection electrode will be removed. Based on this, the first via hole may be a structure with one side being open. In the embodiments of the present disclosure, the description of the “first via hole” is based on a range where the first via hole is located before the second insulating layer is patterned.

In the process of forming the first via hole, the first sub-portion 314 and the second sub-portion 315 are over-etched to a certain extent compared with other portion(s) of the first region 311, resulting in reduction in the thicknesses of the first sub-portion 314 and the second sub-portion 315. In addition, in the process of patterning the second insulating layer, the second sub-portion 315 and other portion(s) of the first region 311 not covered by the first connection electrode 43 are over-etched to a certain extent, resulting in a further reduction in the thickness of the second sub-portion 315. Therefore, the thickness of the first sub-portion 314 is greater than or equal to the thickness of the second sub-portion 315, and the thickness of the second sub-portion 315 is less than the thickness of other portion(s) of the first region 311. Based on this, the portion of the first via hole V1 that is not covered by the first connection electrode 43 may be defined by a region of the second sub-portion 315 (a region where the groove is located).

With continued reference to FIG. 8, a dimension of the second sub-portion 315 in a first direction M1 is D1, where D1 is greater than or equal to 0.3 μm. In this way, it may greatly reduce the risk that the edge of the first connection electrode 43 cannot be in contact with the second sub-portion 315 due to process errors, ensure that at least part of edges of the first connection electrode 43 can be in contact with the second sub-portion 315, and in turn improve the connection reliability between the first connection electrode 43 and the first region 311. The first direction M1 is a direction perpendicular to a boundary L1 where the orthogonal projections of the first sub-portion 314 and the second sub-portion 315 on the base substrate 10 are adjacently connected in the orthogonal projection of the first region 311 on the base substrate 10.

In some embodiments, referring to FIG. 9, the first via hole V1 includes a first sidewall 11 and a second sidewall 12. The first sidewall 11 is located in the first insulating layer 51, and an end of the first sidewall 11 away from the base substrate 10 is connected to the first semiconductor pattern 31. In other words, the first sidewall 11 refers to a sidewall of the first via hole V1 located on a side of the first semiconductor pattern 31 close to the base substrate 10. At least part of the second sidewall 12 is located in the second insulating layer 52. That is, the second sidewall 12 is a remaining sidewall of the first via hole V1 other than the first sidewall 11. A slope angle α1 of the first sidewall 11 is greater than a slope angle α2 of the second sidewall.

During the process of forming the first via hole V1, after the first via hole V1 penetrates through the second insulating layer 52, a portion of the first region 311 and a portion of the first insulating layer 51 are exposed. During continued etching, the first region 311 forms a hard mask to block further etching of the first insulating layer 51 beneath the first region 311, and the portion of the first insulating layer 51 exposed by the first via hole V1 can continue to be etched. Based on this, the first sidewall 11 and the second sidewall 12 with different slope angles in the first via hole V1 are formed.

In some embodiments, the slope angle α1 of the first sidewall 11 is in a range of 60° to 90°: For example, the slope angle α1 of the first sidewall 11 may be in a range of 60° to 70°; or the slope angle α1 of the first sidewall 11 may be in a range of 70°to 80°; or the slope angle α1 of the first sidewall 11 may be in a range of 80° to 90°. For example, the slope angle α1 of the first sidewall 11 may be 60°, 65°, 70°, 75°, 80°, 85°, or 90°, which will not be listed one by one in the embodiments of the present disclosure.

In some embodiments, the slope angle α2 of the second sidewall 12 is in a range of 30° to 60°. For example, the slope angle α2 of the second sidewall 12 may be in a range of 30° to 40°; or the slope angle α2 of the second sidewall 12 may be in a range of 40° to 50°; or the slope angle α2 of the second sidewall 12 may be in a range of 50° to 60°. For example, the slope angle α2 of the second sidewall 12 may be 30°, 35°, 40°, 45°, 50°, 55°, or 60°, which will not be listed one by one in the embodiments of the present disclosure.

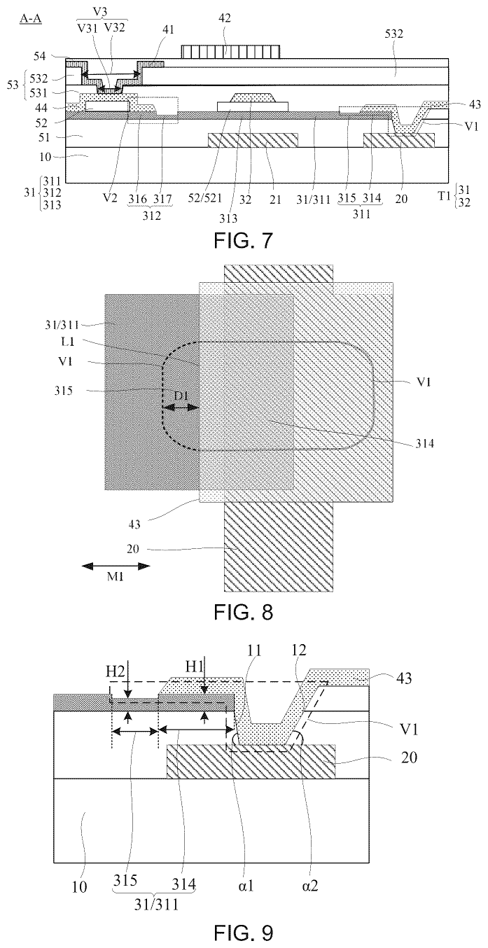

In some embodiments, referring to FIGS. 6 and 7, the array substrate 100 further includes a second via hole V2, a second connection electrode 44, a third insulating layer 53 and a third via hole V3. The third insulating layer 53 is disposed on a side of the second connection electrode 44 away from the base substrate 10.

The second via hole V2 penetrates through the second insulating layer 52 and exposes at least part of the second region 312. For example, an orthogonal projection of the second via hole V2 on the base substrate 10 is located within the orthogonal projection of the second region 312 on the base substrate 10. The second connection electrode 44 is disposed on a side of the second insulating layer 52 away from the base substrate 10. At least part of the second connection electrode 44 is located in the second via hole V2. In the second via hole V2, the second connection electrode 44 is connected to the second region 312. The third via hole V3 penetrates through the third insulating layer 53 and exposes at least part of the second connection electrode 44. At least part of the first electrode 41 is located in the third via hole V3, and the first electrode 41 is connected to the second connection electrode 44 in the third via hole. That is, the first electrode 41 is electrically connected to the second region 312 through the third via hole V3, the second connection electrode 44, and the second via hole V2 in sequence. Compared with a case where the first electrode 41 is directly connected to the second region 312 through a via hole, the first electrode 41 is connected to the second region 312 through the second connection electrode 44, which is conducive to reducing a depth of the via hole through which the first electrode 41 passes, and improving the attaching ability (climbing ability) of the first electrode 41 on a sidewall of the via hole, and in turn reducing the risk of short circuit of the first electrode 41 on the sidewall of the via hole.

In some embodiments, the second connection electrode 44 and the first gate 32 may include the same material and be arranged in the same layer. Compared with a case in which the second connection electrode 44 is formed using an additional film layer and process, the second connection electrode 44 and the first gate 32 include the same material and are arranged in the same layer, which is conducive to simplifying the manufacturing process of the array substrate 100 and reducing the manufacturing cost of the array substrate 100. For example, the second connection electrode 44 and the first gate 32 are formed using the same mask and/or the same material during the same patterning process. For example, the second connection electrode 44, the first gate 32 and the first connection electrode 43 may be arranged in the same layer, and the film layer where the second connection electrode 44, the first gate 32 and the first connection electrode 43 are located is called the gate conductive layer.

Referring to FIGS. 6, 7 and 10, in the case where the second connection electrode 44 and the first gate 32 are arranged in the same layer, at least part of edges of the second connection electrode 44 is in contact with the second region 312. Based on the similar reason that the edge of the first connection electrode 43 is in contact with the first region 311, at least part of edges of the second connection electrode 44 is in contact with the second region 312, which may reduce the connection resistance between the second connection electrode 44 and the second region 312 and improve the connection reliability between the second connection electrode 44 and the second region 312.

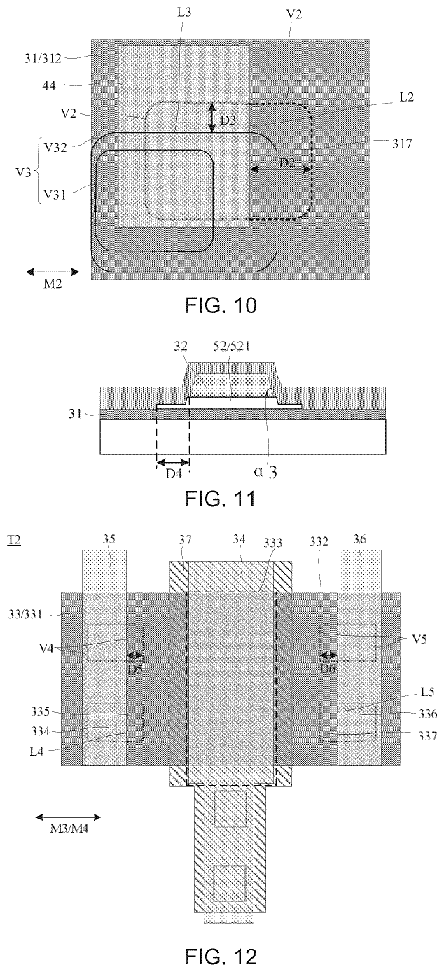

For example, as shown in FIG. 10, an edge of the second connection electrode 44 close to the first channel region 313 is in contact with the second region 312. Of course, the embodiments of the present disclosure are not limited thereto. For example, the second connection electrode 44 may include two edges or three edges that are in contact with the second region 312.

The first transistor T1 is a top-gate transistor. A manufacturing process of the array substrate includes: forming the first semiconductor pattern on the base substrate 10; forming the second insulating layer; forming the gate conductive layer (including the second connection electrode); and performing a conductorization process on the first semiconductor pattern using the gate conductive layer as a mask. In the case where the second connection electrode and the first gate are arranged in the same layer, during the process of performing a conductorization process on the first semiconductor pattern using the gate conductive layer as a mask, a portion of the second region covered by the second connection electrode is not subjected to the conductorization process and has poor conductivity, and a portion of the second region not blocked by the second connection electrode is doped to form a conductor and its resistance is low. At least part of edges of the second connection electrode is in contact with the second region, so that a part of edges of the second connection electrode in contact with the second region may be in contact with the conductorized portion of the second region to reduce the connection resistance between the second connection electrode and the second region.

In some embodiments, as shown in FIGS. 6, 7 and 10, the second region 312 includes a third sub-portion 316 and a fourth sub-portion 317 located in the second via hole V2. The third sub-portion 316 is in contact with the second connection electrode 44. The fourth sub-portion 317 is adjacently connected to an edge of the second connection electrode 44. Orthogonal projections of the fourth sub-portion 317 and the second connection electrode 44 on the base substrate 10 do not overlap. The conductivity of the fourth sub-portion 317 is greater than the conductivity of the third sub-portion 316. In this way, it is conducive to reducing the connection resistance between the edge of the second connection electrode 44 and the second region 312 (the fourth sub-portion 317).

For example, the third sub-portion 316 and the fourth sub-portion 317 include the same semiconductor material, and the third sub-portion 316 and the fourth sub-portion 317 are different in that the fourth sub-portion 317 is subjected to a process (e.g., a doping process) to make it conductive. During the doping process, the first semiconductor pattern 31 is doped using the first gate 32 and the second connection electrode 44 as a mask. The third sub-portion 316 is in contact with the second connection electrode 44 and is located on a side of the second connection electrode 44 close to the base substrate 10. The dopant ions are blocked by the second connection electrode 44, so the third sub-portion 316 is not subjected to the doping process. The orthogonal projection of the fourth sub-portion 317 on the base substrate 10 does not overlap with the orthogonal projection of the second connection electrode 44 on the base substrate 10. That is, the second connection electrode 44 does not block the fourth sub-portion 317. In this case, the fourth sub-portion 317 can be subjected to the doping process and therefore become more conductive (compared to the third sub-portion 316).

In some embodiments, a thickness (a dimension perpendicular to the base substrate 10) of the third sub-portion 316 is greater than or equal to a thickness (a dimension perpendicular to the base substrate 10) of the fourth sub-portion 317. In other words, a portion (the fourth sub-portion 317) in the second via hole V2 not covered by the second connection electrode 44 has a smaller thickness and is recessed toward a side close to the base substrate 10 to form a groove. For example, the thickness of the third sub-portion 316 is greater than the thickness of the fourth sub-portion 317.

For example, a thickness difference between the third sub-portion 316 and the fourth sub-portion 317 may be in a range of 10 Å to 500 Å. For example, the thickness difference between the third sub-portion 316 and the fourth sub-portion 317 may be in a range of 10 Å to 300 Å; alternatively, the thickness difference AH between the third sub-portion 316 and the fourth sub-portion 317 may be in a range of 300 Å to 500 Å. For example, the thickness difference ΔH between the third sub-portion 316 and the fourth sub-portion 317 may be 10 Å, 100 Å, 200 Å, 300 Å, 350 Å, 400 Å or 500 Å, which will not be listed one by one in the embodiments of the present disclosure. For example, the thickness difference between the third sub-portion 316 and the fourth sub-portion 317 may be equal to the thickness difference between the first sub-portion 314 and the second sub-portion 315. first signal line, the first insulating layer, the first semiconductor pattern and the second insulating layer are sequentially formed on the base substrate, and the second via hole penetrating through the second insulating layer is formed, where the second via hole exposes a part of the second region. Then, the first gate and the second connection electrode (the gate conductive layer) are formed on the side of the second insulating layer away from the base substrate; at least part of the second connection electrode is located in the second via hole, and the second connection electrode exposes a part of the first via hole, so that at least part of edges of the second connection electrode can be in contact with the second region in the second via hole. The second insulating layer is patterned using the gate conductive layer as a mask; the second connection electrode exposes a part of the second via hole, so that only a part of the second via hole covered by the second connection electrode will be retained. In the embodiments of the present disclosure, the description of the “second via hole” is based on a range where the second via hole is located before the second insulating layer is patterned.

From a structural point of view, in the process of forming the second via hole, the third sub-portion and the fourth sub-portion are over-etched to a certain extent compared with other portion(s) of the second region, resulting in reduction in the thicknesses of the third sub-portion and the fourth sub-portion. In addition, in the process of patterning the second insulating layer, the fourth sub-portion and other portion(s) of the second region not covered by the second connection electrode are over-etched to a certain extent, resulting in a further reduction in the thickness of the fourth sub-portion. Therefore, the thickness of the third sub-portion is greater than or equal to the thickness of the fourth sub-portion 317. Based on this, the portion of the second via hole V2 that is not covered by the second connection electrode 44 may be defined by a region of the fourth sub-portion 317 (a region where the groove is located).

Referring to FIG. 10, a dimension of the fourth sub-portion 317 in a second direction M2 is D2, where D 2 is greater than or equal to 0.3 μm. In this way, it may greatly reduce the risk that the edge of the second connection electrode 44 cannot be in contact with the fourth sub-portion 317 due to process errors, ensure that at least part of edges of the second connection electrode 44 can be in contact with the fourth sub-portion 317, and in turn improve the connection reliability between the second connection electrode 44 and the second region 312. The second direction M2 is a direction perpendicular to a boundary L2 where the orthogonal projections of the third sub-portion 316 and the fourth sub-portion 317 on the base substrate 10 are adjacently connected in the orthogonal projection of the second region 312 on the base substrate 10.

In some embodiments, referring to FIGS. 6, 7 and 10, orthogonal projections of the second via hole V2 and the third via hole V3 on the base substrate 10 partially overlap. That is, at least part of the orthogonal projection of the second via hole V2 on the base substrate 10 is located outside the orthogonal projection of the third via hole V3 on the base substrate 10, and at least part of the orthogonal projection of the third via hole V3 on the base substrate 10 is located outside the orthogonal projection of the second via hole V2 on the base substrate 10. It can also be considered that the second via hole V2 and the third via hole V3 are partially staggered. In this way, it is possible to avoid that the third via hole V3 completely covers the second via hole V2 or the second via hole V2 completely covers the third via hole V3, and to reduce an overlapping area of the third via hole V3 and the second via hole V2, thereby preventing the third insulating layer 53 from forming a film layer with a large area (equal to an area of the second via hole V2) and large thickness at a position of the second via hole V2. In this way, in the patterning process for forming the third via hole V3, a photoresist residue formed in the third via hole V3 may be reduced.

In some embodiments, referring to FIGS. 6 and 7, the third insulating layer 53 may include the passivation layer 531 and the planarization layer 532 that are stacked in the direction away from the base substrate 10. The third via hole V3 includes: a first sub-hole V31 penetrating through the passivation layer 531, and a second sub-hole V32 penetrating through the planarization layer.

An orthogonal projection of the first sub-hole V31 on the base substrate 10 is located within an orthogonal projection of the second sub-hole V32 on the base substrate 10, and an overlapping area of the orthogonal projection of the first sub-hole V31 on the base substrate and the orthogonal projection of the second via hole V2 on the base substrate 10 is smaller than an overlapping area of the orthogonal projection of the second sub-hole V32 on the base substrate and the orthogonal projection of the second via hole V2 on the base substrate 10. In this way, the overlapping area of the third via hole V3 and the second via hole V2 may be greatly reduced, and the risk of the photoresist residue being formed in the third via hole V3 may be greatly reduced.

The difference between the array substrate 100 shown in FIG. 7 and the array substrate 100 shown in FIG. 6 is as follows. In the array substrate 100 shown in FIG. 6, the first electrode 41 is configured to form a common electrode, the second electrode 42 is configured to form a pixel electrode, and the second electrode 42 is electrically connected to the second connection electrode 44 through the third via hole V3. In the array substrate 100 shown in FIG. 7, the second electrode 42 is configured to form a common electrode, the first electrode 41 is configured to form a pixel electrode, and the first electrode 41 is electrically connected to the second connection electrode 44 through the third via hole V3.

For example, in a case where the array substrate is configured to form a display panel with a high pixels per inch (PPI), the first electrode 41 may be configured to form a pixel electrode; in this case, the array substrate may be used to manufacture a VR/AR display device, for example. In a case where the array substrate is used to form a display panel with a low PPI, the first electrode 41 may be configured to form a common electrode; the first electrode may also shield the second electrode and the first signal line 20 to reduce the impact of voltage fluctuations of the first signal line 20 on the voltage of the second electrode 42; in this case, the array substrate may be used to manufacture a display device such as a notebook and a television.

Referring to FIG. 6, in the case where the first electrode 41 is configured to form a common electrode and the second electrode 42 is configured to form a pixel electrode, the process of manufacturing the array substrate includes sequentially forming the passivation layer 531, the planarization layer 532 and the fourth insulating layer 54; the material of the planarization layer 532 includes an organic material; during the process of forming the planarization layer 532, the second sub-hole V32 may be directly formed through exposing; the fourth insulating layer 54 may be in contact with the passivation layer 531 in the second sub-hole V32; and the fourth insulating layer 54 and the passivation layer 531 may be simultaneously etched to form the first sub-hole V31, and at this time, the first sub-hole V31 also penetrates through the fourth insulating layer 54.

Referring to FIG. 7, in the case where the second electrode 42 is configured to form a common electrode and the first electrode 41 is configured to form a pixel electrode, the process of manufacturing the array substrate includes sequentially forming the passivation layer 531 and the planarization layer 532; the material of the planarization layer 532 includes an organic material; during the process of forming the planarization layer 532, the second sub-hole V32 may be directly formed through exposing; the second sub-hole V32 exposes a part of the passivation layer 531, and the part of the passivation layer 531 exposed by the second sub-hole V32 is etched to form the first sub-hole V31, and the first sub-hole V31 exposes a part of the second connection electrode 44. Then, the process of manufacturing the array substrate further includes forming the first electrode 41 on the planarization layer, where the first electrode passes through the second sub-hole V32 and the first sub-hole V31 to be connected to the second connection electrode. Next, the process of manufacturing the array substrate further includes forming the fourth insulating layer 54 on a side of the first electrode 41 away from the base substrate 10, where the fourth insulating layer 54 covers the first sub-hole V31 and the second sub-hole V32.

In the following embodiments of the present disclosure, the embodiments of the present disclosure will be exemplarily described by taking an example in which the first electrode 41 as shown in FIG. 6 is configured to form a common electrode and the second electrode 42 as shown in FIG. 6 is configured to form a pixel electrode.

In some embodiments, referring to FIG. 10, the orthogonal projection of the second sub-hole V32 on the base substrate 10 includes a first border L3 located within the orthogonal projection of the second via hole V2 on the base substrate 10, and a distance D3 between the first border L3 and a border of the orthogonal projection of the second via hole V2 on the base substrate 10 is greater than or equal to 0.5 μm. In this way, it is possible to minimize the risk of the first border L3 overlapping with the border of the orthogonal projection of the second via hole V2 on the base substrate 10 due to process errors, and it is conducive to reducing an overlapping region of the second sub-hole V32 and the second via hole V2 and reducing the risk of photoresist residue. For example, the distance D3 between the first border L3 and the border of the orthogonal projection of the second via hole V2 on the base substrate 10 may be 0.5 μm, 0.6 μm, 0.7 μm, etc., which will not be listed one by one in the embodiments of the present disclosure.

In some embodiments, referring to FIG. 11, the second insulating layer 52 is disposed between the first semiconductor pattern 31 and the first gate 32, and the second insulating layer 52 includes a first pattern 521 in contact with the first gate 32. An orthogonal projection of the first pattern 521 on the base substrate 10 covers the orthogonal projection of the first gate 32 on the base substrate 10, and a distance D4 between a border of the orthogonal projection of the first pattern 521 on the base substrate 10 and a border of the orthogonal projection of the first gate 32 on the base substrate 10 is in a range of 0.3 μm to 1.5 μm. That is, an area of the first pattern 521 is greater than an area of the first gate 32.

For example, the distance D4 between the border of the first pattern 521 and the border of the first gate 32 may be in a range of 0.3 μm to 0.7 μm; or, the distance D4 between the border of the first pattern 521 and the border of the first gate 32 may be in a range of 0.7 μm to 1.1 μm; or, the distance between the border of the first pattern 521 and the border of the first gate 32 may be in a range of 1.1 μm to 1.5 μm. For example, the distance between the border of the first pattern 521 and the border of the first gate 32 may be 0.3 μm, 0.5 μm, 0.7 μm, 1 μm, 1.1 μm, or 1.5 μm.

For example, during the process of patterning the second insulating layer 52 using the gate conductive layer (the first gate) as a mask, a portion of the second insulating layer 52 close to the first gate 32 is not etched, which results in an edge of the first pattern 521 extending beyond the border of the first gate 32.

In some embodiments, referring to FIG. 11, an angle α3 between a sidewall 321 of the first gate 32 and a plane where the base substrate 10 is located is in a range of 30° to 80°. In other words, a slope angle α3 of the sidewall 321 of the first gate 32 is in a range of 30° to 80°. For example, the angle α3 between the sidewall 321 of the first gate 32 and the plane where the base substrate 10 is located may be in a range of 30° to 55°; or, the angle α3 between the sidewall 321 of the first gate 32 and the plane where the base substrate 10 is located may be in a range of 55° to 80°. For example, the angle α3 between the sidewall 321 of the first gate 32 and the plane where the base substrate 10 is located may be 30°, 40°, 50°, 55°, 65° or 80°, which will not be listed one by one in the embodiments of the present disclosure.

In some embodiments, referring to FIGS. 3 and 12, the second transistor T2 further includes a source 35 and a drain 36, and the source 35 and the drain 36 as well the second gate 34 include the same material and are arranged in the same layer. In this way, the second gate 34, the source 35 and the drain 36 of the second transistor T2 are arranged in the same layer. For example, the second gate 34, the source 35 and the drain 36 are formed using the same mask and/or the same material in the same patterning process, which is conducive to simplifying the manufacturing process of the array substrate and reducing the manufacturing cost of the array substrate.

With continued reference to FIG. 12, the second semiconductor pattern 33 includes a second channel region 333, and a third region 331 and a fourth region 332 that are respectively located on two sides of the second channel region 333. The second channel region 333 is configured to form a channel structure of the second transistor T2. One of the third region 331 and the fourth region 332 is configured to form a source (or a source connection region) of the second transistor T2, and another of the third region 331 and the fourth region 332 is configured to form a drain (or a drain connection region) of the second transistor T2. For example, the third region 331 is configured to form the source connection region, and the fourth region 322 is configured to form the drain connection region.

The array substrate 100 further includes the second insulating layer 52, a fourth via hole V4 and a fifth via hole V5. The second insulating layer 52 is located between the second semiconductor pattern 33 and the second gate 34. The fourth via hole V4 penetrates through the second insulating layer 52 and exposes at least part of the third region 331. The fifth via hole V5 penetrates through the second insulating layer 52 and exposes at least part of the fourth region 332.

At least part of the source 35 is located in the fourth via hole V4, the source 35 is connected to the third region 331 through the fourth via hole V4, and at least part of edges of the source 35 is in contact with the third region 331. In this way, the connection resistance between the source 35 and the third region 331 may be reduced, and the connection reliability between the source 35 and the third region 331 may be improved. At least part of the drain 36 is located in the fifth via hole V5 and is connected to the fourth region 332 through the fifth via hole V5. At least part of edges of the drain 36 is in contact with the fourth region 332. In this way, the connection resistance between the drain 36 and the fourth region 332 is reduced, thereby improving the connection reliability between the drain 36 and the fourth region 332.

In some embodiments, the third region 331 includes a fifth sub-portion 334 and a sixth sub-portion 335 located in the fourth via hole V4. The fifth sub-portion 334 is in contact with the source 35. The sixth sub-portion 335 is adjacently connected to an edge of the source 35, and orthogonal projections of the sixth sub-portion 335 and the source 35 on the base substrate 10 do not overlap. The conductivity of the sixth sub-portion 335 is greater than the conductivity of the fifth sub-portion 334. In this way, it is conducive to reducing the connection resistance between the third region 331 and the source 35. The fourth region 332 includes a seventh sub-portion 336 and an eighth sub-portion 337 located in the fifth via hole V5. The seventh sub-portion 336 is in contact with the drain 36, and the eighth sub-portion 337 is adjacently connected to an edge of the drain 36. Orthogonal projections of the eighth sub-portion 337 and the drain 36 on the base substrate 10 do not overlap. The conductivity of the eighth sub-portion 337 is greater than the conductivity of the seventh sub-portion 336. In this way, it is conducive to reducing the connection resistance between the fourth region 332 and the drain 36.

For example, the fifth sub-portion 334 and the sixth sub-portion 335 include the same semiconductor material, and the fifth sub-portion 334 and the sixth sub-portion 335 are different in that the sixth sub-portion 335 is subjected to a process (e.g., a doping process) to make it conductive. The seventh sub-portion 336 and the eighth sub-portion 337 include the same semiconductor material, and the seventh sub-portion 336 and the eighth sub-portion 337 are different in that the eighth sub-portion 337 is subjected to a process (e.g., a doping process) to make it conductive. For example, during the doping process, the second semiconductor pattern 33 is doped using the second gate 34, the source 35 and the drain 36 as a mask; the fifth sub-portion 334 and the seventh sub-portion 336 are respectively in contact with the source 35 and the drain 36, and are respectively blocked by the source 35 and the drain 36, and therefore are not subjected to the doping process. However, the sixth sub-portion 335 and the eighth sub-portion 337 are not blocked by the second gate 34, the source 35 and the drain 36, and can be subjected to the doping process to become more conductive.

In some embodiments, a thickness of the sixth sub-portion 335 is greater than or equal to a thickness of the fifth sub-portion 334; and/or a thickness of the eighth sub-portion 337 is greater than or equal to a thickness of the seventh sub-portion 336. For example, the thickness of the sixth sub-portion 335 is greater than the thickness of the fifth sub-portion 334; and the thickness of the eighth sub-portion 337 is greater than the thickness of the seventh sub-portion 336.

The manufacturing process of the array substrate may include: forming the second semiconductor pattern and the second insulating layer on the base substrate in sequence; then, forming the fourth via hole V4 and the fifth via hole V5 penetrating through the second insulating layer; then, forming the second gate, the source and the drain (the gate conductive layer) on the side of the second insulating layer away from the base substrate; then, patterning the second insulating layer using the gate conductive layer as a mask. In the embodiments of the present disclosure, the description of the “fourth via hole” is based on a range where the fourth via hole is located before the second insulating layer is patterned, and the description of the “fifth via hole” is based on a range where the fifth via hole is located before the second insulating layer is patterned. From a structural point of view, in the process of forming the fourth via hole and the fifth via hole, the fifth sub-portion 334 and the sixth sub-portion 335 are over-etched to a certain extent compared to other portion(s) of the third region 331, resulting in reduction in the thicknesses of the fifth sub-portion 334 and the sixth sub-portion 335; the seventh sub-portion 336 and the eighth sub-portion 337 are over-etched to a certain extent compared to other portion(s) of the fourth region 332, resulting in reduction in the thicknesses of the seventh sub-portion 336 and the eighth sub-portion. In the process of patterning the second insulating layer, the eighth sub-portion 337, the sixth sub-portion 335, and portions of the third region 331 and the fourth region 332 that are not covered by the gate conductive layer will be over-etched to a certain extent, resulting in further reduction in the thicknesses of the eighth sub-portion 337 and the sixth sub-portion 335; therefore, the thickness of the fifth sub-portion 334 will be greater than the thickness of the sixth sub-portion 335, and the thickness of the seventh sub-portion will be greater than the thickness of the eighth sub-portion 337. Based on this, a portion of the fourth via hole V4 not covered by the source 35 may be defined by a part of the sixth sub-portion 335 (a part with a small thickness), and a portion of the fifth via hole V5 not covered by the drain 36 may be defined by a part of the eighth sub-portion 337 (a part with a small thickness).

In some embodiments, a thickness difference between the sixth sub-portion 335 and the fifth sub-portion 334 is in a range of 10 Å to 500 Å. For example, the thickness difference between the sixth sub-portion 335 and the fifth sub-portion 334 may be in a range of 10 Å to 250 Å, or the thickness difference between the sixth sub-portion 335 and the fifth sub-portion 334 may be in a range of 250 Å to 500 Å. For example, the thickness difference between the sixth sub-portion 335 and the fifth sub-portion 334 may be 10 Å, 100 Å, 200 Å, 250 Å, 350 Å, 400 Å or 500 Å, which will not be listed one by one in the embodiments of the present disclosure.

In some embodiments, a thickness difference between the eighth sub-portion 337 and the seventh sub-portion 336 is in a range of 10 Å to 500 Å. For example, the thickness difference between the eighth sub-portion 337 and the seventh sub-portion 336 may be in a range of 10 Å to 250 Å, or thickness difference between the eighth sub-portion 337 and the seventh sub-portion 336 may be in a range of 250 Å to 500 Å. For example, the thickness difference between the eighth sub-portion 337 and the seventh sub-portion 336 may be 10 Å, 150 Å, 200 Å, 250 Å, 300 Å, 400 Å or 500 Å, which will not be listed one by one in the embodiments of the present disclosure.

In some embodiments, referring to FIG. 12, a dimension D5 of the sixth sub-portion 335 in a third direction M3 is greater than or equal to 0.3 μm. The third direction M3 is a direction perpendicular to a boundary L4 where the orthogonal projections of the fifth sub-portion 334 and the sixth sub-portion 335 on the base substrate 10 are adjacently connected in the orthogonal projection of the third region 331 on the base substrate 10. In this way, it may greatly reduce the risk that the edge of the source 35 cannot be in contact with the sixth sub-portion 335 due to process errors, ensure that at least part of edges of the source 35 can be in contact with the sixth sub-portion 335, and in turn improve the connection reliability between the source 35 and the third region 331. For example, the dimension D5 of the sixth sub-portion 335 in the third direction M3 may be 0.3 μm, 0.4 μm, 0.5 μm or 0.6 μm, which will not be listed one by one in the embodiments of the present disclosure.

With continued reference to FIG. 12, a dimension D6 of the eighth sub-portion 337 in a fourth direction M4 is greater than or equal to 0.3 μm. The fourth direction M4 is a direction perpendicular to a boundary L5 where the orthogonal projections of the seventh sub-portion 336 and the eighth sub-portion 337 on the base substrate 10 are adjacently connected in the orthogonal projection of the fourth region 332 on the base substrate 10. In this way, it may greatly reduce the risk that the edge of the drain 36 cannot be in contact with the eighth sub-portion 337 due to process errors, ensure that at least part of edges of the drain 36 can be in contact with the eighth sub-portion 337, and in turn improve the connection reliability between the drain 36 and the fourth region 332. For example, the dimension D6 of the eighth sub-portion 337 in the third direction M3 may be 0.3 μm, 0.4 μm, or 0.5 μm, which will not be listed one by one in the embodiments of the present disclosure.

For example, referring to FIG. 12, in a case where the source 35 and the drain 36 extend in the same direction and two parallel edges of the source 35 and the drain 36 are in contact with the sixth sub-portion 335 and the eighth sub-portion 337 respectively, the third direction M3 and the fourth direction M4 may be parallel to each other.

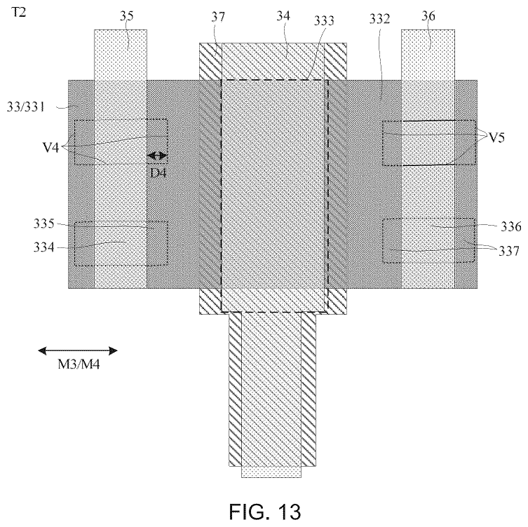

For example, as shown in FIGS. 12 and 13, there may be a plurality of fourth via holes V4. The plurality of fourth via holes V4 may be distributed at intervals in an extending direction of the source 35, and the source 35 is connected to the third region 331 through the plurality of fourth via holes V4. There may be a plurality of fifth via holes V5. The plurality of fifth via holes V5 may be distributed at intervals in an extending direction of the drain 36, and the drain 36 is connected to the fourth region 332 through the plurality of fifth via holes V5.

In some embodiments, as shown in FIG. 12, one edge of the source 35 is in contact with the third region 331. It is conceivable that, in some other embodiments, referring to FIG. 13, the source 35 may have two edges in contact with the third region 331. For example, both edges of the source 35 in the third direction M3 are in contact with the third region 331. Corresponding to the source 35, the drain 36 may also have two or more edges in contact with the fourth region 332.

With continued reference to FIGS. 12 and 13, the second transistor T2 in the array substrate 100 may further include a third gate 37. The third gate 37 is disposed on a side of the second semiconductor pattern 33 close to the base substrate 10, and the third gate 37 is electrically connected to the second gate 34. In this way, the second transistor T2 may be of a dual-gate structure including the second gate 34 and the third gate 37, and a conductive interface may be created on each of upper and lower sides of the second channel region 333, which is conducive to improving an on-state current of the second transistor T2. An orthogonal projection of the third gate 37 on the base substrate 10 covers an orthogonal projection of the second gate 34 on the base substrate 10. In this way, the third gate 37 can block the second channel region 333, which is conducive to reducing the risk of light incident on the second channel region 333, and in turn improving the stability of the second channel region 333 under illumination and reducing the risk of voltage drift of the second transistor T2.

For example, the third gate 37 and the first signal line 20 may include the same material and be arranged in the same layer. For example, the third gate 37 and the first signal line 20 may be formed using the same mask and/or the same material in the same patterning process. In this way, it is conducive to simplifying the manufacturing process of the array substrate and reducing the manufacturing cost of the array substrate.

In some embodiments, as shown in FIG. 6, the array substrate 100 may further include a shielding pattern 21. The shielding pattern 21 is disposed on a side of the first semiconductor pattern 31 close to the base substrate 10. An orthogonal projection of the shielding pattern 21 on the base substrate 10 covers an orthogonal projection of the first channel region 313 on the base substrate 10. The shielding pattern 21 may reduce light directed to the first channel region 313 of the first semiconductor pattern 31, which is conducive to improving the stability of the first transistor under illumination.

In some embodiments, the shielding pattern 21 and the first signal line 20 may include the same material and be arranged in the same layer. For example, the shielding pattern 21 and the first signal line 20 may be formed using the same mask and/or the same material in the same patterning process. In this way, it is conducive to simplifying the manufacturing process of the array substrate and reducing the manufacturing cost of the array substrate.

The foregoing descriptions are merely specific implementations of the present disclosure, but the protection scope of the present disclosure is not limited thereto. Any changes or replacements that a person skilled in the art could conceive of within the technical scope of the present disclosure shall be included in the protection scope of the present disclosure. Therefore, the protection scope of the present disclosure should be determined by the protection scope of the claims.

What is claimed is:

1. An array substrate, having a display region and a peripheral region, the array substrate comprising:
a base substrate;
a first signal line disposed on the base substrate and at least partially located in the display region;
a first transistor located in the display region and disposed on a side of the first signal line away from the base substrate, wherein the first transistor includes a first semiconductor pattern and a first gate disposed on a side of the first semiconductor pattern away from the base substrate; and
a second transistor located in the peripheral region, wherein the second transistor includes a second semiconductor pattern and a second gate disposed on a side of the second semiconductor pattern away from the base substrate; and the first gate and the second gate are arranged in a same layer.

2. The array substrate according to claim 1, wherein the first semiconductor pattern includes a first channel region, and a first region and a second region that are respectively located on two sides of the first channel region; the array substrate further comprises:
a first insulating layer located between the first signal line and the first semiconductor pattern;
a second insulating layer located on the side of the first semiconductor pattern away from the base substrate;
a first via hole penetrating through at least the first insulating layer and the second insulating layer, exposing at least part of the first signal line, and exposing at least part of the first region; and
a first connection electrode disposed on a side of the second insulating layer away from the base substrate, wherein the first connection electrode is electrically connected to the first signal line and the first region in the first via hole.

3. The array substrate according to claim 2, wherein
the first connection electrode and the first gate include a same material and are arranged in a same layer; and
at least part of edges of the first connection electrode is in contact with the first region.

4. The array substrate according to claim 3, wherein
the first region includes a first sub-portion and a second sub-portion located in the first via hole; the first sub-portion is in contact with the first connection electrode; the second sub-portion is adjacently connected to an edge of the first connection electrode; orthogonal projections of the second sub-portion and the first connection electrode on the base substrate do not overlap; and a conductivity of the second sub-portion is greater than a conductivity of the first sub-portion; and
wherein a thickness of the first sub-portion is greater than or equal to a thickness of the second sub-portion; and/or
a dimension of the second sub-portion in a first direction is greater than or equal to 0.3 μm, the first direction being perpendicular to a boundary where orthogonal projections of the first sub-portion and the second sub-portion on the base substrate are adjacently connected in an orthogonal projection of the first region on the base substrate.

5.-6. (canceled)

7. The array substrate according to claim 2, wherein
the first via hole includes a first sidewall and a second sidewall; the first sidewall is located in the first insulating layer, and an end of the first sidewall away from the base substrate is connected to the first semiconductor pattern; at least part of the second sidewall is located in the second insulating layer; and a slope angle of the first sidewall is greater than a slope angle of the second sidewall; and
wherein the slope angle of the first sidewall is in a range of 60° to 90°, and/or the slope angle of the second sidewall is in a range of 30° to 60°.

8. (canceled)

9. The array substrate according to claim 2, further comprising:
a second via hole penetrating through the second insulating layer and exposing at least part of the second region;
a second connection electrode disposed on the side of the second insulating layer away from the base substrate and at least partially located in the second via hole, wherein the second connection electrode is connected to the second region in the second via hole;
a third insulating layer disposed on a side of the second connection electrode away from the base substrate;
a third via hole penetrating through the third insulating layer and exposing at least part of the second connection electrode; and
a first electrode at least partially located in the third via hole, wherein the first electrode is connected to the second connection electrode in the third via hole.

10. The array substrate according to claim 9, wherein
the second connection electrode and the first gate include a same material and are arranged in a same layer; and
at least part of edges of the second connection electrode is in contact with the second region.

11. The array substrate according to claim 10, wherein
the second region includes a third sub-portion and a fourth sub-portion located in the second via hole; the third sub-portion is in contact with the second connection electrode; the fourth sub-portion is adjacently connected to an edge of the second connection electrode;
orthogonal projections of the fourth sub-portion and the second connection electrode on the base substrate do not overlap; and a conductivity of the fourth sub-portion is greater than a conductivity of the third sub-portion; and
wherein a thickness of the third sub-portion is greater than or equal to a thickness of the fourth sub-portion; and/or
a dimension of the fourth sub-portion in a second direction is greater than or equal to 0.3 μm, the second direction being perpendicular to a boundary where orthogonal projections of the third sub-portion and the fourth sub-portion on the base substrate are adjacently connected in an orthogonal projection of the second region on the base substrate.

12.-13. (canceled)

14. The array substrate according to claim 9, wherein
orthogonal projections of the second via hole and the third via hole on the base substrate partially overlap.

15. The array substrate according to claim 14, wherein
the third insulating layer includes a passivation layer and a planarization layer that are stacked in a direction away from the base substrate;
the third via hole includes a first sub-hole penetrating through the passivation layer and a second sub-hole penetrating through the planarization layer; an orthogonal projection of the first sub-hole on the base substrate is located within an orthogonal projection of the second sub-hole on the base substrate; and an overlapping area of the orthogonal projection of the first sub-hole on the base substrate and an orthogonal projection of the second via hole on the base substrate is smaller than an overlapping area of the orthogonal projection of the second sub-hole on the base substrate and the orthogonal projection of the second via hole on the base substrate.

16. The array substrate according to claim 15, wherein
the orthogonal projection of the second sub-hole on the base substrate includes a first border located within the orthogonal projection of the second via hole on the base substrate; and a distance between the first border and a border of the orthogonal projection of the second via hole on the base substrate is greater than or equal to 0.5 μm.

17. The array substrate according to claim 2, wherein
the second insulating layer is disposed between the first semiconductor pattern and the first gate, and includes a first pattern in contact with the first gate;
an orthogonal projection of the first pattern on the base substrate covers an orthogonal projection of the first gate on the base substrate; and a distance between a border of the orthogonal projection of the first pattern on the base substrate and a border of the orthogonal projection of the first gate on the base substrate is in a range of 0.3 μm to 1.5 μm.

18. (canceled)

19. The array substrate according to claim 1, wherein the second transistor further includes a source and a drain, and the source and the drain as well as the second gate include a same material and are arranged in a same layer.

20. The array substrate according to claim 19, wherein the second semiconductor patter includes a second channel region, and a third region and a fourth region that are respectively located on two sides of the second channel region; the array substrate further comprises:
a second insulating layer disposed between the second semiconductor pattern and the second gate;
a fourth via hole penetrating through the second insulating layer and exposing at least part of the third region; and
a fifth via hole penetrating through the second insulating layer and exposing at least part of the fourth region;
wherein at least part of the source is located in the fourth via hole and is connected to the third region through the fourth via hole; at least part of edges of the source is in contact with the third region; at least part of the drain is located in the fifth via hole and is connected to the fourth region through the fifth via hole; and at least part of edges of the drain is in contact with the fourth region.

21. The array substrate according to claim 19, wherein
the third region includes a fifth sub-portion and a sixth sub-portion located in the fourth via hole; the fifth sub-portion is in contact with the source; the sixth sub-portion is adjacently connected to an edge of the source; orthogonal projections of the sixth sub-portion and the source on the base substrate do not overlap; a conductivity of the sixth sub-portion is greater than a conductivity of the fifth sub-portion;
the fourth region includes a seventh sub-portion and an eighth sub-portion located in the fifth via hole; the seventh sub-portion is in contact with the drain; the eighth sub-portion is adjacently connected to an edge of the drain; orthogonal projections of the eighth sub-portion and the drain on the base substrate do not overlap; and a conductivity of the eighth sub-portion is greater than a conductivity of the seventh sub-portion.

22. The array substrate according to claim 20, wherein
a dimension of the sixth sub-portion in a third direction is greater than or equal to 0.3 μm, the third direction being perpendicular to a boundary where orthogonal projections of the fifth sub-portion and the sixth sub-portion on the base substrate are adjacently connected in an orthogonal projection of the third region on the base substrate; and/or
a dimension of the eighth sub-portion in a fourth direction is greater than or equal to 0.3 μm, the fourth direction being perpendicular to a boundary where orthogonal projections of the seventh sub-portion and the eighth sub-portion on the base substrate are adjacently connected in an orthogonal projection of the fourth region on the base substrate.

23. The array substrate according to claim 22, wherein
a thickness of the fifth sub-portion is greater than or equal to a thickness of the sixth sub-portion; and/or a thickness of the seventh sub-portion is greater than or equal to a thickness of the eighth sub-portion; and
wherein a thickness difference between the sixth sub-portion and the fifth sub-portion is in a range of 10 Å to 500 Å; and/or a thickness difference between the eighth sub-portion and the seventh sub-portion is in a range of 10 Å to 500 Å.

24. (canceled)

25. The array substrate according to claim 1, wherein the second transistor further includes:
a third gate disposed on a side of the second semiconductor pattern close to the base substrate, wherein an orthogonal projection of the third gate on the base substrate covers an orthogonal projection of the second gate on the base substrate, and the third gate is electrically connected to the second gate.

26. The array substrate according to claim 1, further comprising:
a first insulating layer located between the first signal line and the first semiconductor pattern and including a first material layer and a second material layer that are stacked in a direction away from the base substrate, wherein a material of the first material layer includes silicon nitride, and a material of the second material layer includes silicon oxide;
a second insulating layer located between the first semiconductor pattern and the first gate, wherein a material of the second insulating layer includes silicon oxide; and
a passivation layer, a planarization layer, a first electrode, a fourth insulating layer, and a second electrode that are sequentially arranged in the direction away from the base substrate, wherein the passivation layer includes a third material layer and a fourth material layer that are stacked in the direction away from the base substrate, a material of the third material layer includes silicon oxide, a material of the fourth material layer includes silicon nitride, and a material of the fourth insulating layer includes silicon nitride; and
wherein an atomic ratio of silicon to nitrogen in the silicon nitride of the first material laver is in a range of 1:1 to 1:0.5; an atomic ratio of silicon to oxygen in the silicon oxide of the second material layer is in a range of 1:1 to 1:2; an atomic ratio of silicon to oxygen in the silicon oxide of the second insulating laver is in a range of 1:1 to 1:2: an atomic ratio of silicon to oxygen in the silicon oxide of the third material layer is in a range of 1:1.5 to 1:2; an atomic ratio of silicon to nitrogen in the silicon nitride of the fourth material layer is in a range of 1:1 to 1:0.6; and an atomic ratio of silicon to nitrogen in the silicon nitride of the fourth insulating laver is in a range of 1:1 to 1:0.6.

27. (canceled)

28. A display panel, comprising:
the array substrate according to claim 1;
a color filter substrate arranged opposite to the array substrate; and
a liquid crystal layer disposed between the array substrate and the color filter substrate.
